(19) United States
(12) Patent Application Publication
(10) Pub. No.: US 2021/0301141 A1
(43) Pub. Date: Sep. 30, 2021

(54) CASCADE SURFACE MODIFICATION OF COLLOIDAL QUANTUM DOT INKS ENABLES EFFICIENT BULK HOMOJUNCTION PHOTOVOLTAICS

(71) Applicant: QD SOLAR INC., TORONTO (CA)

(72) Inventors: MIN-JAE CHOI, SEOUL (KR); FRANCISCO PELAYO GARCIA DE ARQUER, TORONTO (CA); SJOERD HOOGLAND, TORONTO (CA); EDWARD H. SARGENT, TORONTO (CA)

(21) Appl. No.: 17/214,113

(22) Filed: Mar. 26, 2021

Related U.S. Application Data
(60) Provisional application No. 63/000,207, filed on Mar. 26, 2020.

(51) Int. Cl. C09C 1/14; C09C 3/08; H01L 51/00

(52) U.S. Cl. CPC C09C 1/14; C09C 3/08; H01L 51/0077; B82Y 30/00; C01P 2002/52; C01P 2004/64; C01P 2006/40

(57) ABSTRACT

Disclosed herein are homogeneous CQD bulk homojunction solids prepared through a cascade surface modification (CSM) strategy. The CSM includes an initial halogenation step of CQD surfaces to attain an initial sufficient passivation; and a subsequent step that reprograms CQD surfaces with functional ligands to control the doping character and solubility properties of the resulting CQD inks. The resulting p-type and n-type CQDs exhibit a distinct potential difference, which induces a built-in electric field between the constituent classes of CQDs. By controlling the colloidal solubility of the inks, homogeneous CQD bulk homojunction films have been achieved, whereas it is shown that the use of prior ink strategies results in inhomogeneous films as a result of poor miscibility. The homogeneous CQD bulk homojunction films exhibit a 1.5-fold increase in the carrier diffusion length and outperforms previously-reported CQD solar cells, achieving a record PCE of 13.3%.

### FIELD

The present application concerns the technical field of thin-film photovoltaics and optoelectronic devices, and particularly to quantum dot nanocrystal films and solar cell devices. More particularly the present disclosure provides a method of surface modification of colloidal quantum dot inks for enabling efficient bulk homojunction photovoltaics.

### BACKGROUND

Colloidal semiconductor nanocrystals such as quantum dots (CQDs) have attracted intense attention for optoelectronic applications including light-emitting diodes, photodetectors, lasers, and photovoltaic devices¹. The broad tunability of their optical and electrical properties through size and surface chemistry modification² enables bottom-up design for function and performance. The understanding and manipulation of these properties has triggered continued progress in the performance of CQD devices. In solar cells, improvements in synthesis, surface passivation, and device architecture have enabled advances in power conversion efficiency (PCE), which has now reached certified values of 12% in single-junction solar cells³.

Major strides in improving the performance of CQD solar cells have been achieved through increasing the carrier diffusion length (LD), which provides improved charge extraction efficiency³. The diffusion length is determined by the lifetime and the mobility of minority carriers. One strategy for increasing the diffusion length is to minimize the deep electronic trap states at CQD surface. Ligand exchanges enable surface passivation of CQDs, which results in improved carrier transport and longer carrier lifetime in CQD solids.

In an alternate strategy, one may architect devices that favour charge transport and extraction in CQD solids: in a bulk heterojunction, photoexcited electrons and holes are separated into distinct phases and then collected via charge-selective contacts, which results in extended carrier lifetimes, reduced recombination rates, and therefore longer diffusion lengths. CQD/semiconducting polymer blends, or two different CQD materials, represent materials combinations used to implement bulk heterojunctions.

A single bandgap choice in CQD materials can also be used, forming bulk homojunctions in which the two phases are distinguished by their doping⁴. The density of states of ligand/CQD systems is influenced by ligand functionalization (arising from their electron-donating vs. electron-withdrawing character)^{1,5-6}, and, as a result, the use of different ligands provides another degree of freedom in control over the doping level in CQDs^{1,2}.

However, despite their advantages in carrier extraction and transport, CQD bulk homojunction devices have yet to outperform⁴ planar devices due to the difficulty in making both p-type and n-type CQD inks with complete surface passivation. In particular, previously-explored ligand-exchange approaches for p-type CQD inks have resulted in surface defects that find their origins in the steric hindrance of the doping ligands⁷, a fact that prevents comprehensive surface coverage (FIG. 1A). The two ink types also need to be fully miscible with one another. Instability in blend CQD inks leads aggregation of CQDs and non-uniform morphology in the final films, which are detrimental to optoelectronic device performance.

### SUMMARY

As noted above, control over carrier type and doping levels in semiconductor materials is key for optoelectronic applications. In colloidal quantum dots (CQDs), these properties can be tuned by surface chemistry modification, but this has so far been accomplished at the expense of reduced surface passivation and compromised colloidal solubility which has precluded the realization of advanced architectures such as CQD bulk homojunction solids. Disclosed herein are homogeneous CQD bulk homojunction solids prepared through a cascade surface modification (CSM) strategy. The CSM is comprised of an initial halogenation step of CQD surfaces to attain an initial sufficient passivation; and a subsequent step that reprograms CQD surfaces with functional ligands to control the doping character and solubility properties of the resulting CQD inks. The resulting p-type and n-type CQDs exhibit a distinct potential difference, which induces a built-in electric field between the constituent classes of CQDs. By controlling the colloidal solubility of the inks, we achieve homogeneous CQD bulk homojunction films, whereas we show that the use of prior ink strategies results in inhomogeneous films as a result of poor miscibility. The homogeneous CQD bulk homojunction films exhibit a 1.5-fold increase in the carrier diffusion length and outperforms previously-reported CQD solar cells, achieving a record PCE of 13.3%.

In sum, we document an invention that enables control over doping character and solubility of CQD inks while preserving conformal surface passivation.

The present disclosure provides an inorganic nanocrystal having a facetted surface, comprising:

doping agents bound to the facetted surface of the nanocrystal to render the nanocrystal either an n-type or p-type doped nanocrystal; and stabilisation agents bound to the surface of the facetted surface of the nanocrystal to provide long-term stability of the nanocrytal in a selected solvent.

The present disclosure also provides a method of preparing the doped and solvent stabilized inorganic nanocrystal, the inorganic nanocrystal having a facetted surface with long chain ligands attached thereto, the method comprising the steps of:
exposing the nanocrystal to a solvent containing doping agents and stabilisation agents for inducing a ligand exchange reaction to remove substantially all the long chain ligands to be replaced by the stabilisation agents and doping agents bound to the facetted surface, the doping agents being selected to render the nanocrystal either an n-type or p-type doped nanocrystal, and the stabilisation agents being selected to provide long-term stability of the nanocrytal in the solvent.

The inorganic nanocrystal may further comprise passivating agents bound to the facetted surface of the inorganic nanocrystal.

The passivating agents may be any one or combination of halides and metal chalcogenide complexes.

The passivating agents may be any one or combination of sulfide complexes. These sulfide complexes may be selected from the group consisting of sodium sulfide (Na₂S), ammonium sulfide ((NH₄)₂S), potassium sulfide (K₂S), tin sulfide and copper suldie.

The doping and stabilization agents may be the same compound, being a combined doping and stabilization agent, with compound having a first moeity which interacts with the surface of the facetted surface to provide doping of the inorganic nanocrystal, and the compound having a second moeity which interacts with the selected solvent to stabilize the inorganic nanocrystal in the selected solvent.

The combined doping and stabilization agent may be selected from the group consisting of cysteamine, mercaptoethanol, hydroxythiophenol, aminothiophenol, mercaptopropionic acid and thioglycerol.

When the doping and stabilization agent are the same compound, the ratio of the doping agents to the passivation agents may be about 2:1.

Conversely, the doping and stabilization agents may be different compounds, wherein the stabilization agent has a first moeity which bonds to the facetted surface, and wherein the stabilization agent has a second moeity which interacts with the selected solvent to stabilize the inorganic nanocrystal in the selected solvent.

When the doping and stabilization agents are different compounds, the doping agent may be selected from the group consisting of ethanethiol, propanethiol, formic acid, acetic acid, propionic acid and thiophenol.

When the doping and stabilization agents are different compounds, the stabilization agent is selected from the group consisting of ethylenediamine, propylenediamin and butylamine.

The multifaceted nanocrystal may be selected from the group consisting of Bi₂S₃, FeS₂ (pyrite), FeS, iron oxide, ZnO, TiO₂, copper sulfide, PbS, PbSe, PbTe, CdSe, CdS, Si, Ge, copper zinc tin sulfide (CZTS), HgTe, CdHgTe and copper indium gallium diselenide (CIGS); InAs, InₓGa₁₋ₓAs (X: 0-1) AgS, AgSe; and core-shell structures based on these CQDs as the core; ternary or multinary compounds based on the above.

The inorganic nanocrystals are characterized in that they exhibit long-term stability in the solvent of at least 30 minutes and potentially months to years.

The present disclosure also provides a nano-composite material, comprising:
a mixture of two or more types of inorganic nanocrystals having facetted surfaces, each type having a composition different from the other types, and/or each type having a different size from the other types;
each type of inorganic nanocrystal having doping agents bound to the facetted surfaces of the nanocrystals to render the nanocrystals either an n-type or p-type doped nanocrystal; and
each type of inorganic nanocrystal having stabilisation agents bound to the facetted surfaces to provide long-term stability of the nanocrytal in a selected solvent, the stabilization agents bound to the facetted surfaces of one type of inorganic nanocrystal being selected to not interact with the facetted surfaces of the other types of inorganic nanocrystals.

In addition, there is provided a method of preparing a solvent stabilized nano-composite material, comprising:
providing two or more types of inorganic nanocrystals having facetted surfaces, each type having a composition different from the other types, and/or each type having a different size from the other types;
separately exposing each type to a preselected a solvent containing doping agents and stabilisation agents for inducing a ligand exchange reaction to remove substantially all long chain ligands initially present on surfaces of the each type of inorganic nanocrystals to be replaced by the stabilisation agents and doping agents bound to the facetted surface, the doping agents being selected to render the mixture of each type either an n-type or p-type doped nanocrystal, and the stabilisation agents being selected to provide long-term stability of each type in the solvent; and
mixing the doped and stabilized types in the solvent.

The method may further include, prior to exposing the inorganic nanocrystal to the solvent containing the doping and stabilisation agents, exposing the inorganic nanocrystal to a solvent containing passivation agents, thereby inducing a ligand exchange reaction to remove substantially all the long chain ligands to be replaced by the passivating agents to form passivated nanocrystals, followed by exposing the passivated nanocrystals to a solvent containing the doping and stabilisation agents to replace some of the passivating agents and bind to at least some sites not occupied by the passivating agents.

The passivating agents may be any one or combination of halides and metal chalcogenide complexes.

The passivating agents are any one or combination of sulfide complexes. These sulfide complexes may be selected from the group consisting of sodium sulfide (Na₂S), ammonium sulfide ((NH₄)₂S), potassium sulfide (K₂S), tin sulfide and copper suldie.

The doping and stabilization agent may be the same compound, being a combined doping and stabilization agent, the compound having a first moeity which interacts with the surface of the facetted surface to provide doping of the inorganic nanocrystal, the compound having a second moeity which interacts with the selected solvent to stabilize the inorganic nanocrystal in the selected solvent.

The combined doping and stabilization agent may be selected from the group consisting of cysteamine, mercaptoethanol, hydroxythiophenol, aminothiophenol, mercaptopropionic acid and thioglycerol.

When the doping and stabilization agent are the same compound, a ratio of the doping agents to the passivation agents may be about 2:1.

Alternatively, the doping and stabilization agents may be different compounds, wherein the stabilization agent has a first moeity which bonds to the facetted surface, and the stabilization agent has a second moeity which interacts with the selected solvent to stabilize the inorganic nanocrystal in the selected solvent.

The nano-doping agent may be selected from the group consisting of ethanethiol, propanethiol, formic acid, acetic acid, propionic acid and thiophenol.

The stabilization agent may be selected from the group consisting of ethylenediamine, propylenediamin and butylamine.

The two or more types of inorganic nanocrystals are selected from the group consisting of Bi₂S₃, FeS₂ (pyrite), FeS, iron oxide, ZnO, TiO₂, copper sulfide, PbS, PbSe, PbTe, CdSe, CdS, Si, Ge, copper zinc tin sulfide (CZTS), HgTe, CdHgTe and copper indium gallium diselenide (CIGS); InAs, InₓGa₁₋ₓAs (X: 0-1) AgS, AgSe; and core-shell structures based on these CQDs as the core; ternary or multinary compounds based on the above.

The nano-composite material is characterized in that it exhibits long-term stability of least 30 minutes and up to years in the selected solvent.

A further understanding of the functional and advantageous aspects of the invention can be realized by reference to the following detailed description and drawings.

### BRIEF DESCRIPTION OF THE DRAWINGS

Embodiments disclosed herein will be more fully understood from the following detailed description thereof taken in connection with the accompanying drawings, which form a part of this application, and in which:

FIG. 1A is a schematic drawing showing the present strategy to achieve tunable doping and passivation of CQD inks synthesized via cascade surface modification (CSM), in which: first we halogenate CQD surfaces to attain an initial sufficient passivation; and only then do we reprogram the CQD surface with functional molecules that are tailored to control doping character, energy level, and colloidal properties of the resulting CQD inks

FIG. 1B shows photoluminescence quantum yield (PLQY) results of CQD inks synthesized by conventional exchange and CSM. The CQD inks synthesized by CSM exhibit 3× times higher PLQY than the CQD inks by conventional method;

which confirms conformal surface passivation of CSM-CQD inks.

FIG. 1C shows chemical structure of various functional ligands employed herein.

FIG. 1D shows phase transfer of CQDs from octane to dimethylformamide (DMF) upon ligand-exchange with functional ligands. Conventional exchange exhibits precipitation of CQDs due to low colloidal solubility, while CSM exchange enables to form stable colloids in DMF phase.

FIG. 1E is the measured energy levels of the CQDs before surface reprogramming (halogenated) and after surface reprogramming (functionalized), showing that surface reprogramming with functional molecules renders the CQDs p-type character.

FIG. 1F is the kelvin probe force microscopy (KPFM) mapping image, which confirms the difference in energy level between n-type CQDs (halogenated) and p-type CQDs (functionalized).

FIG. 2A is an sulfur 2p spectra of the n-type CQDs (halogenated) and p-type CQDs (functionalized) measured by X-ray photoelectron spectroscopy. The p-type CQDs show C—S signal, which reveals attachment of thiol functional group at the CQD surface. In contrast, the n-type CQDs does not have C—S signal.

FIG. 2B is an iodide 3d spectra of the n-type CQDs (halogenated) and p-type CQDs (functionalized) measured by X-ray photoelectron spectroscopy. The signal of the p-type CQDs is largely decreased compared to the n-type CQDs, because thiol function group substitutes the iodide surface ligands.

FIG. 2C is an atomic ratio of the n-type CQDs (halogenated) and p-type CQDs (functionalized) calculated by X-ray photoelectron spectroscopy result, showing that surface reprogramming results in an increase of sulfur ratio and a decrease of iodide ratio. It is because functional molecules in the surface reprogramming substitutes the iodide surface ligands.

FIGS. 3A, 3B show ultraviolet photoelectron spectroscopy results that are used to calculate energy levels in FIG. 1E.

FIG. 4A is an atomic force microscopy (AFM) topographic image that is used in FIG. 1F.

FIG. 4B is a 3-dimensional KPFM potential image that is used in FIG. 1F.

FIG. 5A is a measurement to calculate electron mobility of CQDs, which shows that n-type CQDs has 2.2× higher electron mobility compared to p-type CQDs.

FIG. 5B is a measurement to calculate hole mobility of CQDs, which shows that p-type CQDs has 1.6× higher hole mobility compared to n-type CQDs.

FIG. 6A is a schematic drawing showing the process to fabricate CQD bulk homojunction solids. To achieve this, n-type CQDs and p-type CQDs are homogeneously miscible in one solvent (left image) without precipitation.

FIG. 6B is an absorbance measurement to show the poor solubility of control CQD inks (mixture of n-type CQD inks and control p-type CQD inks). It displays rapid precipitation and aggregation after 15 minutes.

FIG. 6C is a summary of absorbance measurement result of the control CQD inks and CSM CQD inks (mixture of n-type CQD inks and CSM CQD inks). We define ‘intensity loss’ and ‘half-width half maximum (HWHM)’ in the FIG. 6B. This plot shows clearly that the CSM CQD inks are much stable than the control CQD inks based on these two factors.

FIG. 6D is a grazing-incidence small-angle scattering mapping image of the mixed CSM CQD ink. Red color indicates strong signal that CQDs are highly ordered with the indicated domain size.

FIG. 6E is a grazing-incidence small-angle scattering mapping image of the mixed control CQD ink. The red signal in q_{xy}:1.5˜2.0 nm⁻¹ disappears compared to FIG. 6D, which indicates aggregation of CQDs.

FIG. 6F is a plot of the result in FIG. 6D and FIG. 6E showing that the mixed CSM CQD inks retains the morphology of n-type CQDs and p-type CQDs in the solid film state, while the control CQD inks show aggregation between those dots.

FIG. 7A is a photograph image of CSM CQD inks dissolved in butylamine solvent. MPA, ME, CTA refers different organic molecules used in CSM process.

FIG. 7B is a summary plot of the absorbance result of CQD inks in FIG. 7A showing that CTA molecules results in most stable CQD inks in the case of butylamine solvent.

FIG. 8 is a grazing-incidence small-angle scattering results of n-type CQDs, CSM p-type CQDs, and mixed CQDs showing that n-type CQDs and CSM p-type CQDs retain their morphology after mixed and fabricated in the film.

FIG. 9A is an ultraviolet photoelectron spectroscopy results of acceptor CQD film that is used for characterization in FIG. 10.

FIG. 9B is an energy level comparison between acceptor CQD film (FIG. 9A) and our n-type CQD and CSM p-type CQD films.

FIG. 10A is a schematic drawing showing a limitation of carrier transport in conventional CQD film structure (left image, n-type CQD only). In a new bulk homojunction structure (right image), each carrier {electron, hole} is separated and transported through n-type CQDs and p-type CQDs, respectively, enabling extending the effective carrier transport length. To prove this, the acceptor CQD films (yellow dots) were put on top of the CQD film. These acceptor CQD films form type-I heterojunction with donor CQD films (either n-type CQD only or bulk homojunction) that carriers in the donor CQD film transport and are quenched at the acceptor CQD film (FIG. 9B). We therefore excite bottom of the donor CQD film and monitor photoluminescence (PL) intensity of the acceptor CQD film. As a thickness of the donor CQD films increases, the PL intensity starts to decrease because there is a carrier recombination before carriers reach to the acceptor CQD films. We plot the PL intensity of the acceptor CQD film as a function of the donor CQD film thickness (FIG. 10C) to calculate the carrier diffusion length of the donor CQD films.

FIG. 10B is a result of measurement mentioned in FIG. 10A in the case of bulk homojunction film. The intensity of photoluminescence (PL) starts to decrease once the CQD film is thicker than certain thickness.

FIG. 10C is a plotting of experiment results for n-type CQD only, p-type CQD only, and CQD bulk homojunction. The fitting (solid line) shows that bulk homojunction reaches the highest intensity at the thickest CQD film (˜380 nm), indicating an increase of transport length.

FIG. 11 is a plot of photoluminescence versus wavelength of mixed CQDs with n-type CQDs and CSM produced p-type CQDs showing that they are stable in solution-state.

FIG. 12 are plots of normalized absorbance (left side) and normalized photoluminescence (right side), versus wavelength of n-type CQDs and CSM p-type CQDs showing that the CSM p-type CQDs exhibit redshift in absorbance and photoluminescence compared to the n-type CQDs, due to the sulfur attachment at the CQD surface.

FIGS. 13A, 13B are plots of normalized absorbance versus wavelength (FIG. 13A) and normalized photoluminescence versus wavelength (FIG. 13B) of the various combination of CQDs showing that n-type CQDs and CSM p-type CQDs retain their distinct surface chemicals in the mixed solution-state.

FIG. 14A is schematic drawing showing carrier transfer between n-type CQD and CSM p-type CQD: electron transfers to n-type CQD and hole transfers to CSM p-type CQD.

FIG. 14B is a photoluminescence results of n-type CQD, CSM p-type CQD, and mixed CQD (bulk homojunction). In the case of bulk homojunction, the intensity of photoluminescence decreases which proves the schematic drawing in FIG. 14A.

FIG. 15A is a schematic drawing showing carrier transfer in mixed CQDs consist of small bandgap n-type CQDs and large bandgap n-type CQDs. If small bandgap n-type CQDs are excited, there is no carrier transfer due to the unmatched energy level.

FIG. 15B is a schematic drawing showing carrier transfer in mixed CQDs consist of small bandgap n-type CQDs and large bandgap p-type CQDs. If small bandgap n-type CQDs are excited, hole transfers to p-type CQD occurs due to the favorable energy level matching.

FIG. 15C is a wavelength versus time decay transient absorption measurement mapping image in the case of FIG. 15A. Red color indicates higher absorption change and blue color indicates lower absorption change. The deep blue color represents background signal that there is no change in the absorption. In FIG. 15C, there is no peak at the red dash line (wavelength=980 nm), which indicates there is no carrier transfer between CQDs.

FIG. 15D is a transient absorption measurement mapping image in the case of FIG. 15B. Red color indicates higher absorption change and blue color indicates lower absorption change. The deep blue color represents background signal that there is no change in the absorption. In FIG. 15D, a new signal appears at the red dash line (wavelength=980 nm), which indicates there is no carrier transfer between CQDs.

FIG. 15E is a plotting of FIG. 15C at the wavelength of 980 nm (large bandgap n-type CQD) and 1090 nm (small bandgap n-type CQD), showing that there is no carrier transfer.

FIG. 15F is a plotting of FIG. 15D at the wavelength of 980 nm (large bandgap p-type CQD) and 1090 nm (small bandgap n-type CQD), showing that there is carrier transfer from small bandgap n-type CQD to large bandgap p-type CQD.

FIG. 16A, 16B are raw data of transient absorption data that are used in FIG. 15A and FIG. 15B, respectively.

FIG. 17A is a cross-sectional image measured by scanning electron microscopy (SEM) showing the structure of devices.

FIG. 17B is an efficiency of solar cells with different mixed ratio between n-type CQDs and p-type CQDs. At the 1:1˜1:2 mixed ratio of n-type CQD and p-type CQD shows the highest efficiency of solar cells.

FIG. 17C is an efficiency of solar cells fabricated using n-type CQD and p-type CQD and bulk homojunction. We plot the efficiency as a function of thickness of CQD film, which indicates that bulk homojunction device shows the higher absolute efficiency and the larger optimized thickness compared to the n-type CQD device and the p-type CQD device.

FIG. 17D is a plot of the current density versus voltage characteristics of solar cells shown in FIG. 17C when they show the best efficiency.

FIG. 17E is external quantum efficiency measurement of solar cells fabricated using n-type CQD and bulk homojunction. It shows that bulk homojunction device harvests more light compared to n-type CQD device.

FIG. 18 are histograms of CQD solar cells fabricated using n-type CQD and p-type CQD and bulk homojunction, showing that bulk homojunction devices exhibit higher efficiency than the other devices with high reproducibility.

FIG. 19 shows the device stability results when the device operates continuously under 1 sun illumination. It reveals that bulk homojunction device is stable under continuous operation, which retains ˜90% of initial efficiency after 100 hours of operation.

FIGS. 20A, 20B and 20C are large-area device fabrication with CQD bulk homojunction films, showing that it retains high efficiency in the case of large-area device, in which:

FIG. 20A is photograph image of the large-area device,

FIG. 20B is plot of current density versus voltage of the device, and

FIG. 20C is external quantum efficiency of the device.

FIG. 21A is an absorption versus wavelength plot of CQD bulk heterojunction devices when different bandgap CQDs are used as a n-type CQD and p-type CQD.

FIG. 21B is an efficiency of solar cells using CQD bulk heterojunction films. The efficiency is measured with c-Si filter showing the efficiency of CQD devices that can be added to c-Si solar cells. It also displays that CQD bulk heterojunction devices exhibit higher efficiency compared to control devices consists of only n-type CQDs, which shows CSM and mixed CQD strategy can be applied to wide range of bandgap of CQDs.

FIG. 21C is plot of external quantum efficiency (EQE) versus wavelength which shows the results of CQD bulk heterojunction devices described in FIG. 21B with different CQD film thickness.

FIG. 21D is a plot of current density versus voltage showing the current density-voltage characteristic of CQD bulk heterojunction device with c-Si filter (thickness of CQD film=730 nm). The resultant efficiency of 1.37% can be added to c-Si solar cells by putting CQD devices in the backside of c-Si solar cells.

FIG. 22 is a schematic drawing showing the efficient carrier transport in CQD bulk homojunction, which enables extending carrier transport length. A magnified image of the circled portion displays electron transfers to n-type CQD and hole transfers to p-type CQD.

### DETAILED DESCRIPTION

Without limitation, the majority of the systems described herein are directed to differently doped nanocrystal ensembles for enhanced solar energy harvesting. As required, embodiments of the present invention are disclosed herein. However, the disclosed embodiments are merely exemplary, and it should be understood that the invention may be embodied in many various and alternative forms.

The accompanying figures, which are not necessarily drawn to scale, and which are incorporated into and form a part of the instant specification, illustrate several aspects and embodiments of the present disclosure and, together with the description therein, serve to explain the principles of the process of producing multibandgap nanocrystal ensembles for solar-matched energy harvesting. The drawings are provided only for the purpose of illustrating select embodiments of the apparatus and as an aid to understanding and are not to be construed as a definition of the limits of the present disclosure. For purposes of teaching and not limitation, the illustrated embodiments are directed to multibandgap nanocrystal ensembles for solar-matched energy harvesting.

As used herein, the terms, “comprises” and “comprising” are to be construed as being inclusive and open ended, and not exclusive. Specifically, when used in the specification and claims, the terms, “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately”, when used in conjunction with ranges of dimensions of particles, compositions of mixtures or other physical properties or characteristics, are meant to cover slight variations that may exist in the upper and lower limits of the ranges of dimensions so as to not exclude embodiments where on average most of the dimensions are satisfied but where statistically dimensions may exist outside this region. It is not the intention to exclude embodiments such as these from the present disclosure.

As used herein, the phrase colloidal quantum dots refers to semiconducting particles that have a size below the Exciton Bohr radius. Quantum dot bandgaps may range from about 0.5 electron Volts (eV) to about 3 eV, and may include but are not limited to, PbS, PbSe, Ag₂S, Ag₂Se, to mention just a few.

As used herein, the phrase “interparticle separation” refers to the shortest distance from the surface of one quantum dot to that of the adjacent quantum dot.

As used herein, the phrase “passivating agent” means organic/inorganic molecules that bond with the surface of the quantum dot to eliminate trap state of quantum dot.

As used herein, the phrase “doping agent” means organic/inorganic molecules that bond with surface of the quantum dot to control density of states of quantum dots.

As used herein, the phrase “stabilisation agent” means organic/inorganic molecules that bonds with the surface of the quantum dot to provide colloidal solubility of quantum dot.

As used herein, the phrase “long-term stability” refers to a time that more than 90% of the quantum dots retains a stable colloid in selected solvents, not showing precipitation, which as observed in the present disclosure is months and possibly years.

Disclosed herein is a method to synthesize and produce p-type nanocrystal inks with tunable surface passivation. This is achieved by an initial halogenation step that infiltrates sites otherwise inaccessible to bulky functional doping ligands, followed by a second step where organic molecules with electron donating capabilities (e.g., cysteamine, 2-mercaptoethanol, 1-thioglycerol) are grafted to nanocrystal surface p-type inks achieve 3× higher photoluminescence quantum yield compared to conventional inks.

The organic molecule consists of two moieties; one provides doping character and another enables to tune the solubility of CQD inks. The moiety that renders doping (e.g. —SH, —COOH) have higher binding energy with the CQD surface, thus it binds to the surface. The moiety that provides solubility (e.g. —NH₂, —OH) is not attached to the surface and interacts with the solvent. For example, thiol group (—SH) render CQDs p-type, the other functional group (—NH₂, —OH, —CH₃) enables to tune the solubility of the CQD inks. Various length scale of molecules can be applied (0.3 nm˜2 nm), but it is observed that increasing the length of organic molecules decreases the conductivity of resulting CQD films.

Thus, the present method provides control over doping character, colloidal solubility, and surface passivation of CQDs. This is achieved by cascade method, which comprises an initial surface halogenation to attain sufficient passivation, and a followed surface reprogramming with various functional ligands to control the doping and solubility. The first initial halogenation step infiltrates sites with halogens that are otherwise inaccessible to bulky functional doping ligands. The second step incorporates organic molecules with tunable electron withdrawing/donating character such as described above. This results in inks that can be tuned from n-type to p-type character without compromising surface passivation.

The doping level of the CQDs can be controlled by the ratio of molecule reprogramming at the CQD surface. It is determined by the amount of organic molecule injection in the second exchange. This new surface engineering strategy demonstrates use of a wider set of organic molecules on nanoparticle surfaces controlling colloid stability. This is achieved by the choice of the functional group exposed to the solvent. This enables tunable colloidal solubility combined with optoelectronic tunability by changing functional groups of functional ligands.

These tunable colloids exhibit a stable colloid stability whereas conventional colloids show 80% of precipitation after 25 min. The tunable colloids also retain absorption and luminescence features such as half-width half-max, peak-to-valley ratio in quantum dots, Urbach tails and Stokes shift. Half-width half-max of the colloids increases 4% after about 30 min, while conventional colloids show a rapid broadening (49%) after 25 min.

The nanoparticle inks with different optoelectronic properties (density of surface defects and carrier type/density) and colloid chemistry may be intermixed, and the resulting colloid is stable and the initial nanoparticle sub populations retain their initial chemistry and optoelectronic properties. The blended inks may be tuned to achieve semiconductor solids with different architectures, nanomorphology and optoelectronic properties.

Architectures enabled by this may comprise bulk homojunction (BHJ) solids comprised of of nanoparticles with identical stoichiometries, size and bandgap but with different doping density; bulk heterojunction solids comprised of nanoparticles with different bandgaps; bulk homo/heterojunction solids with tunable domain distribution and percolation paths at the nanoscale level. The resulting semiconductor solid exhibits differentiated domains with different optoelectronic properties and surface chemistry stemming from the nature of the constituent inks.

Studies of the CQD inks synthesized by the present CSM method disclosed herein show they exhibit three (3) times higher photoluminescence quantum yield (18%) compared to conventional CQD inks, while both inks are capped with same 1-thioglycerol (TG) ligands.

The present CSM method enables a use of a library of functional molecules at the surface of CQDs including TG, 2-mercaptoethanol (ME), cysteamine (CTA), 4-hydroxythiophenol (HTP), 4-aminothiophenol (ATP), and malonic acid (MA).

Surface reprogramming with functional molecules renders CQDs p-doping that exhibits ˜0.2 eV Fermi level offset with n-type CQDs (before reprogramming).

Blend CQD inks comprised of p-type and n-type CQDs enables the fabrication of CQD bulk homojunction films. These new CQD bulk homojunction materials demonstrate a significant improvement in the carrier diffusion length relative to the individual carrier diffusion length of each component (n-type and p-type). The CQD bulk homojunction provides a distinct physical path for each of the carriers (electron or hole). This leads to improved diffusion length by a factor of 1.5× compared with the previous best CQD films.

The different bandgaps of each n-and p-doped CQDs blended to produce the CQD film enables the fabrication of CQD bulk heterojunction films and can be applied to universally large sizes of CQDs (characterized by low bandgaps), which enables the fabrication of IR CQD bulk heterojunction devices showing IR light harvesting beyond the bandgap c-Si.

Different inorganic precursors that induce cation exchange with CQDs can also be applied through CSM method. Inorganic doping materials such as Agl, AgNO₃, and Bil₃.

The original CQD nanocrystal solutions may be comprised of nanocrystals with different bandgaps that can also possess a different doping and a different surface functionalization. The different nanocrystal solutions can be subjected to various surface modifications such as solution exchange before their mixture and assembly.

The hybrid material may be comprised of different type of CQDs, such as, but not limited to, Bi₂S₃, FeS₂ (pyrite), FeS, iron oxide, ZnO, TiO₂, copper sulfide, PbS, PbSe, PbTe, CdSe, CdS, Si, Ge, copper zinc tin sulfide (CZTS), HgTe, CdHgTe and copper indium gallium diselenide (CIGS); InAs, InₓGa₁₋ₓAs (X: 0-1) AgS, AgSe; and core-shell structures based on these CQDs as the core; ternary or multinary compounds based on the above.

Embodiments of the present composite materials will be studied, characterized and assembled into a photovoltaic device elucidated in the non-limiting Example below.

### NON-LIMITING EXAMPLE

### Methods and Characterization

### Methods

### COD Synthesis

Oleic-acid-capped PbS CQDs at 950 nanometers (nm) (1.31 electron volts (eV)) were synthesized based on following method. Lead(II) oxide (0.9 g), oleic acid (3 milliliters (mL)), and octadecene (20 mL) were mixed in a three-neck flask and heated to 120° C. under vacuum for 2 hours (h) and then filled with N₂. A stock solution, 0.24 mL of hexamethyldisilathiane dissolved in 8 mL of octadecene, was then injected rapidly into the flask for PbS CQD synthesis. Then, the CQD solution was slowly cooled to room temperature. Acetone was added to precipitate the QD solution, which was then redispersed in toluene. The CQDs were further purified twice by adding a mixture of acetone and methanol. Finally, the QDs were dissolved in octane (50 milligrams (mg)/mL).

### CSM Process And Film Fabrication

For both n-type and p-type CQD inks, PbS CQDs at 950 nm were used. Precursor solution was prepared by dissolving lead halides (lead iodide 0.1 molar (M) and lead bromide 0.02 M) and NH₄Ac (0.055 M) in dimethylformamide (DMF). A 5 mL of CQD solution dissolved in octane (7 mg/mL) was added to 5 mL of precursor solution. Then the solution was mixed vigorously for 1-2 minutes (min) until CQDs were transferred to DMF phase. The octane phase was discarded and DMF solution was washed with octane three times. The DMF solution was precipitated by adding toluene and dried in vacuum. The CQD solids were redispersed in butylamine (BTA). This CQD inks were used as n-type CQDs. To produce p-type inks, above DMF solution was further treated with second surface modification. Thiol solution was prepared by dissolving cysteamine in DMF (0.1 M). The thiol solution was slowly dropped to the DMF solution with gentle stirring (range of 100 microliters (μL) to 400 μL) and precipitated by adding toluene. The CQD solids were dried in vacuum and redispersed in butylamine (BTA). This CQD inks were deposited on a substrate by single-step spin-coating to achieve CQD films. The process was carried out under ambient air conditions.

### COD Solar Cell Fabrication

The ZnO nanoparticles were synthesized using a published method⁶, which reference (6) is incorporated herein in its entirety by reference. The ZnO nanoparticles were spin-cast on an indium tin oxide (ITO) substrate at 3000 revolutions per minute (r.p.m) for 30 seconds (s). Then CQD inks were spin-cast onto the ZnO/ITO substrate. The blend CQD inks (mixture of n-type CQD inks and p-type CQD inks) were used to fabricate bulk homojunction devices. The CQD films were annealed at 70° C. for 5 min in N₂-filled glove box. Two PbS-EDT layers were then deposited as a hole-transport layer. Oleic-acid-capped CQDs were spin-cast, and then soaked with 0.01 vol % 1,2-ethanedithiol in propionitrile solution for 30 s, followed by three repetitions of washing using propionitrile. Finally, 120 nm of Au was deposited via e-beam evaporation as the top electrode. We note that the use of propionitrile provides higher device performance compared with acetonitrile which was used in prior works³.

### Solar Cell Measurements

The active area (0.049 cm²) was determined by the aperture placed between the devices and the AM1.5 solar simulator (Sciencetech class A). Current-voltage characteristics were measured with the aid of a Keithley 2400 source measuring unit under simulated AM1.5 illumination. Devices were tested under a continuous nitrogen flow. The current-voltage (I-V) curves were scanned from −0.70 volts (V) to +0.1 V at 0.02 V interval steps without wait time between voltage steps. The spectral mismatch was calibrated using a reference solar cell (Newport). EQE spectra were taken by subjecting the solar cells to chopped (220 Hertz (Hz)) monochromatic illumination (400 W Xe lamp passing through a monochromator and appropriate cutoff filters). Newport 818-ultraviolet (UV) and Newport 838-infrared (IR) photodetectors were used to calibrate the output power. The response of the cell was measured with a Lakeshore preamplifier feeding into a Stanford Research 830 lock-in amplifier at short-circuit conditions.

### Transient Absorption Measurements

Femtosecond pulses at 1030 nm with a 5 kHz repetition rate were produced using a regeneratively-amplified Yb:KGW laser (PHAROS, Light Conversion). A portion of the beam was used to pump an optical parametric amplifier (ORPHEUS, Light Conversion) to serve as a narrowband pump tuned between 1000 and 1200 nm. The other portion of the beam power was focused into a sapphire crystal to generate a white-light supercontinuum probe (900-1300 nm window with various optical filters). Both pulses were directed into a commercial transient absorption spectrometer (Helios, Ultrafast). A time window up to 8 nanoseconds (ns) was obtained by delaying the probe pulse relative to the pump pulse. The time resolution of these experiments was ˜300 fempto seconds (fs) (pulse duration of the pump pulse). All experiments were performed with fluence less than or equal to ˜600 microjoules (μJ) cm⁻² to minimize Auger recombination¹¹.

### Grazing-Incidence Small-Angle X-Ray Spectroscopy (GISAXS)

GISAXS measurements were conducted at the Hard X-ray MicroAnalysis (HXMA) beamline of the Canadian Light Source (CLS). An energy of 17.998 keV (wavelength (λ)=0.6888 Å) was selected using a Si (111) monochromator. Patterns were collected on a SX165 CCD camera (Rayonix) placed at a distance of 157 mm from the sample. A lead beamstop was used to block the direct beam. Images were calibrated using LaB6 and processed via the Nika software package and the GIXSGUI MATLAB plug-in.

### One-Dimensional Carrier Diffusion Length Measurements

For the acceptor CQD layer (E_{g}=1.0 eV), a 5 mL of oleic-acid-capped CQD solution dissolved in octane (7 mg/mL) was added to 5 mL of precursor solution (lead iodide 0.1 M and lead bromide 0.02 M, and NaAc 0.055 M in DMF). Then the solution was mixed vigorously for 5 min until CQDs were transferred to the DMF phase. The octane phase was discarded and the DMF solution was washed with octane three times. The DMF solution was precipitated by adding toluene. The supernatant was removed, and the precipitated material was dried in vacuum. The CQD solids were redispersed in mixture of BTA:DMF (4:1). The acceptor CQD inks were spin-coated on glass substrates with a thickness of 50˜60 nm. Then, donor CQD layer (E_{g}=1.3 eV) was deposited on top of the acceptor CQD layer using n-type CQD inks, p-type CQD inks, or blend CQD inks (n-type:p-type=1:1). Samples were illuminated through the donor CQD layer side using a monochromated Xe lamp at 400 nm wavelength. The normalized PL intensity as a function of donor CQD layer thickness is fit using the equation¹⁰:

$$P {L}_{accepto r} = - \frac{α}{{α}^{2} {L}_{d}^{2} / τ - 1 / τ} ( \frac{1}{{L}_{d}} {e}^{- d / {L}_{d}} \frac{{e}^{d / {L}_{d}} - {e}^{- α d}}{{e}^{- d / {L}_{d}} - {e}^{d / {L}_{d}}} + α {e}^{- α d} - \frac{1}{{L}_{d}} {e}^{d / {L}_{d}} \frac{{e}^{- d / {L}_{d}} - {e}^{- α d}}{{e}^{d / {L}_{d}} - {e}^{- d / {L}_{d}}} )$$

where L_{d} is the carrier diffusion length, d is the thickness of donor CQD layer, and α is the absorption coefficient, and τ is the carrier lifetime.

### Other Characterization

Photoluminescence measurements were carried out using a Horiba Fluorolog Time Correlated Single Photon Counting system equipped with UV/Vis/NIR photomultiplier tube detectors, dual grating spectrometers, and a monochromatized xenon lamp excitation source. Optical absorption measurements were carried out in a Lambda 950 UV-Vis-IR spectrophotometer. XPS measurements were carried out using a Thermo Scientific K-Alpha system, with a 75 eV pass energy, and binding energy steps of 0.05 eV. All signals are normalized to Pb. Atomic force microscopy and scanning Kelvin probe microscopy were done using an Asylum Research Cypher AFM. Samples were electrically grounded and AC160-R2 silicon probes with a titanium-iridium coating were used. Imaging was done in tapping mode and a nap pass was done to measure the contact potential difference. Spectroscopic ellipsometry was performed using a Horiba UVISEL Plus Extended Range ellipsometer with a 200-ms integration time, a 10 nm step size and a 1-mm diameter spot size. Three incident angles (60,65 and 70 degrees) were used. Soda-lime glass slides were used as substrates for each individual material, with their back sides covered with opaque adhesive tape to eliminate back-reflections. Fitting was performed using the Horiba DeltaPsi2 software. Dispersion functions composed of 4 Voigt oscillators achieved fits with χ2<1.

### Results

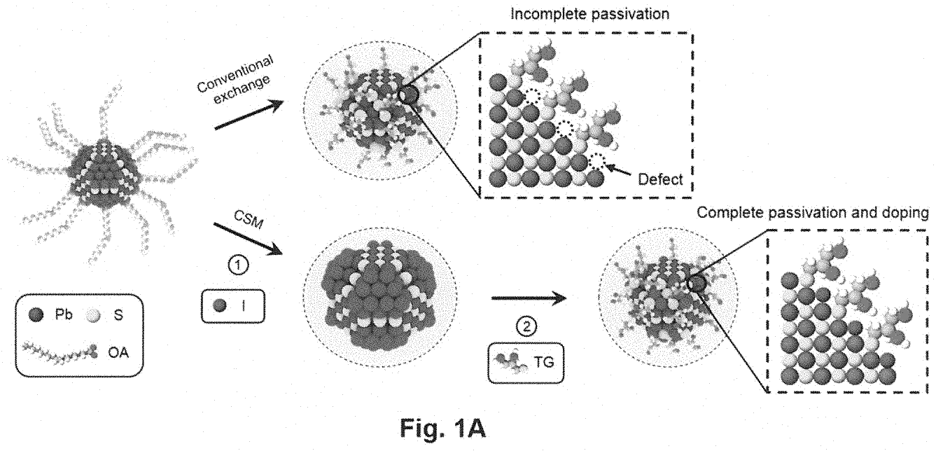

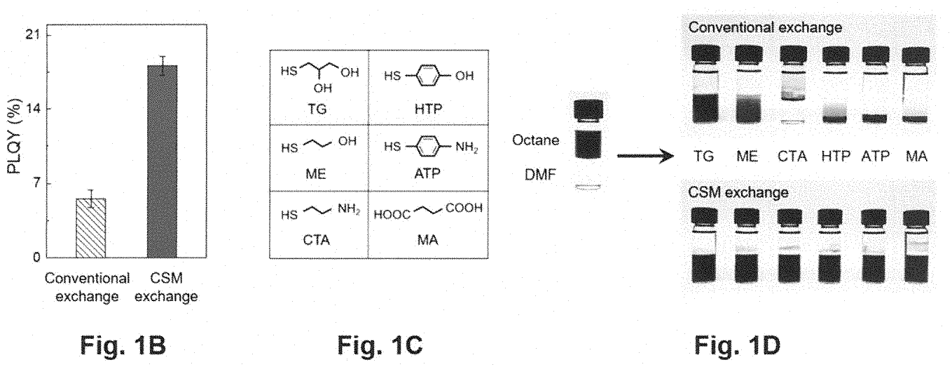

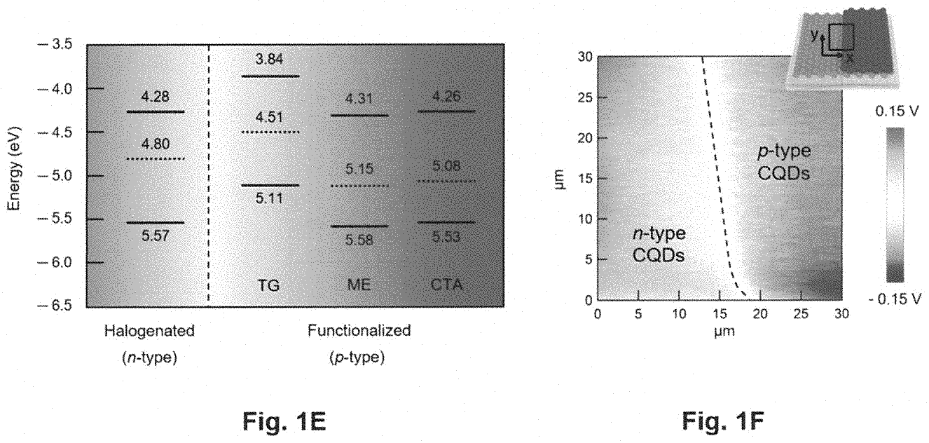

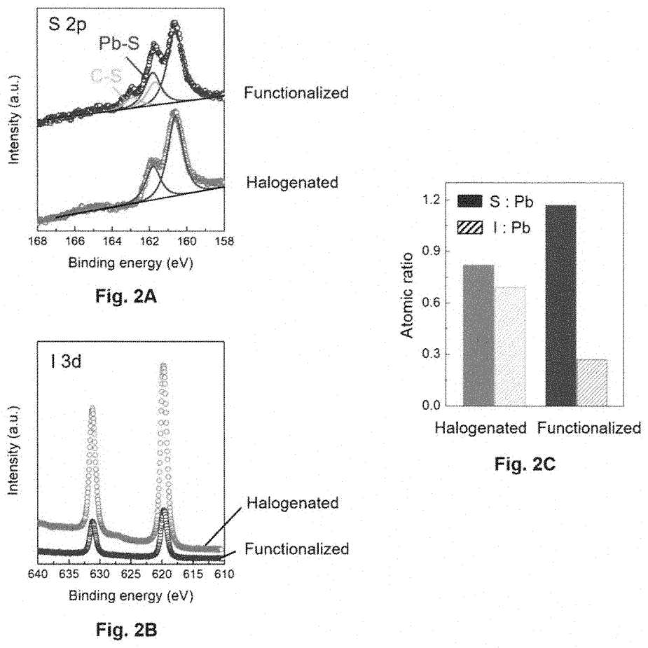

N-type and p-type CQD inks were synthesized via the CSM process depicted in FIG. 1A. Initially, CQDs are capped with oleic acid and dispersed in the octane. The first step is surface halogenation of CQDs with lead halide anions to obtain n-type CQD inks, after which the dots are transferred to dimethylformamide (DMF) in which they form a stable colloid. In a second step, we reprogram the CQD surface—rich in lead halide anions—with thiol ligands, introduced to render the CQD inks p-type. X-ray photoelectron spectroscopy (XPS) was used to monitor the surface reprogramming of CQD inks. The measurements revealed bound thiolate peak in XPS S 2p spectra and a strong decrease of the XPS I 3d peak (FIG. 2).

To evaluate the degree of surface passivation of CQD inks, the materials' photoluminescence quantum yield (PLQY) was measured. Prior solution-phase ligand exchange methods give a low PLQY of 6% due to a lack of surface passivation (FIG. 1B). In contrast, the CSM-programmed CQD inks using the same 1-thioglycerol (TG) ligands exhibit a 3-fold higher PLQY of 18%. This highlights the key role of the initial halogenation step to infiltrate sites otherwise inaccessible to bulky organic ligands.

FIG. 1C shows the chemical structure of various functional ligands [TG, 2-mercaptoethanol (ME), cysteamine (CTA), 4-hydroxythiophenol (HTP), 4-aminothiophenol (ATP), and malonic acid (MA)]. In contrast with previous ink strategies, which were limited to the use of TG, the CSM method enables use of a wider set of molecules on CQD surfaces, and achieves stable colloids (FIG. 1d), showcasing the versatility of the method.

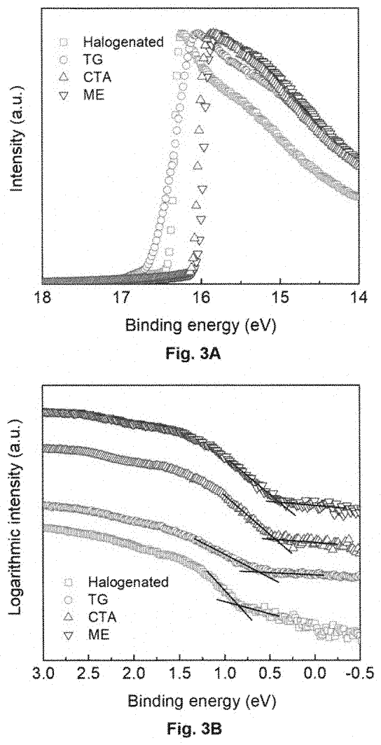

The surface reprogramming with thiol ligands increases the S/Pb atomic ratio of CQD inks from 0.81 to 1.15 (FIG. 2), and we found this stoichiometric control induces p-type characteristics as evidenced by ultraviolet photoelectron spectroscopy (FIG. 1E and FIG. 3). The n-type CQD inks are tuned to p-type after surface reprogramming: the energy difference between the valence band and the Fermi level decreases from 0.77 to 0.6 (TG), 0.43 (ME), and 0.45 (CTA), respectively.

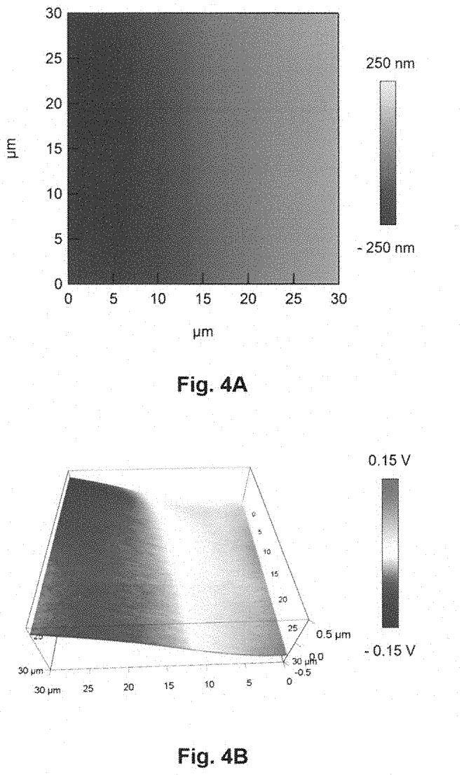

Kelvin probe force microscopy (KPFM) was used to measure the surface potential difference between n-type and p-type CQDs to assess whether net doping of each phase was retained following self-assembly to the final CQD solid (FIG. 1F). The inset shows the schematic image of the film structure. The two-dimensional KPFM potential image shows a ˜0.2 eV change at the interface between p-type CQDs and n-type CQDs, giving evidence of the energy offset in Fermi levels between n- and p-type CQDs within the thin films. The local variation in surface potential is due to variation in the film thickness over the area studied in KPFM, which is confirmed by atomic force microscopy topographic image (FIG. 4).

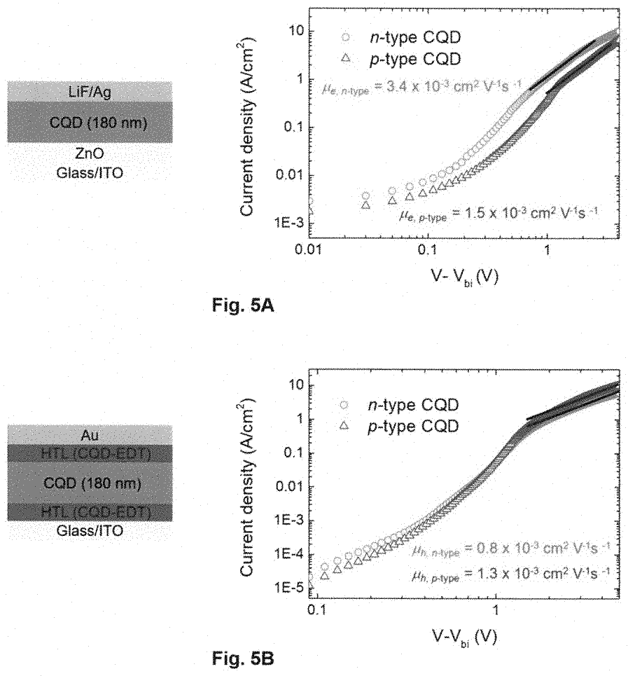

The effect of doping on carrier transport properties was investigated using the space charge limited current (SCLC) method⁸. Hole- and electron-only devices fabricated with n-type CQDs and p-type CQDs, respectively, reveal that the p-type CQDs exhibit a higher hole mobility (μh=1.3×10⁻³ V/cm·s) and lower electron mobility (μₑ=1.5×10⁻³ V/cm·s) compared to the n-type CQDs (μₕ=8×10⁻⁴ V/cm·s; μₑ=3×10⁻³ V/cm·s) (FIG. 5), a trend also seen in prior report⁸.

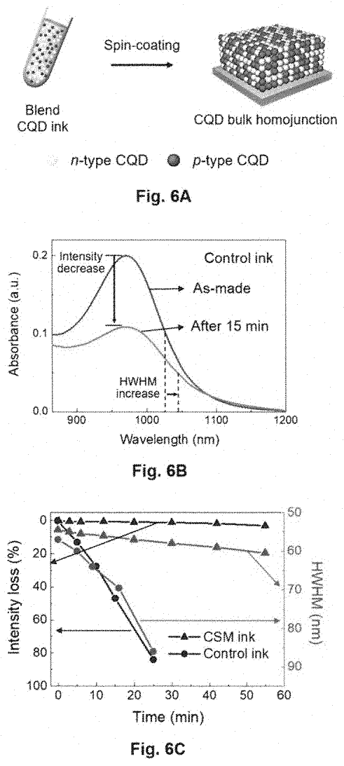

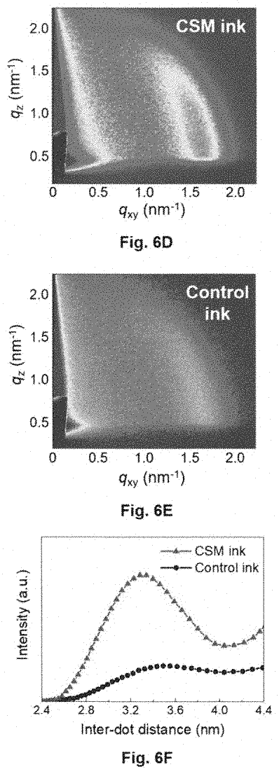

CQD bulk homojunction films were fabricated by using these oppositely-doped inks (FIG. 6A). In this step, the solution miscibility of two inks is needed to realize homogeneous CQD films. Precipitation, aggregation and size polydispersity of CQDs occur when blend inks are not colloidally stable, as a result of heterogeneous fusion between CQDs. This leads to energetic disorder that inhibits carrier transport in the films. CQD fusion and polydispersity are observed as inhomogeneous broadening in absorption spectra, where the intensity of the bandedge exciton peak will decrease, and its half width at half maximum (HWHM) will increase (FIG. 6B). Measuring the absorption spectra over time shows that the mixture of n-type and p-type CQD inks produced by conventional solution exchange methods (control inks) undergo rapid degradation of their initial properties (FIG. 6C).

Since it was previously demonstrated that n-type CQD inks are dispersed well in butylamine (BTA) due to surface lead halides³, the inventors sought to tailor solubility of p-type CQD inks by using CSM method to form stable colloids of blend inks in BTA. The colloidal solubility of p-type inks is determined by the other functional group in thiol ligands (—L in SH—R—L) because thiols (—SH) strongly bind to CQD surface. The inventors hypothesized that the strength of the hydrogen bond of the —L termination with respect to BTA would be the key determinant of colloid stability. A competing scenario where —L moieties possessed a stronger hydrogen bond with one another compared to BTA would promote CQD aggregation and colloid precipitation. Only when the strength of hydrogen bond for L—BTA is balanced or stronger than L—L can p-type CQD inks form stable colloids in BTA.

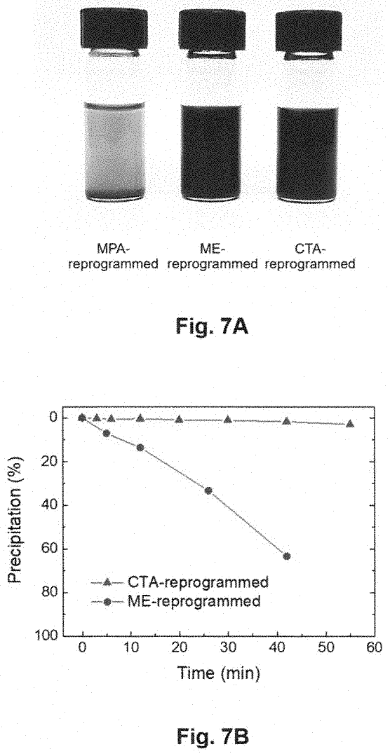

Given the strength of hydrogen bonds between each functional group (COOH—COOH>OH—OH>NH₂—NH₂), the inventors reasoned that NH₂ would be the most well-suited functional group to form stable colloids in BTA because BTA contains NH₂ group. We then synthesized CSM-programmed CQD inks employing various bifunctional thiol ligands containing different functional groups (COOH, OH, NH₂). The experiments revealed that the NH₂ group (CTA) enables the formation stable colloids, whereas the OH group (ME) exhibited limited stability, and the COOH groups (3-mercaptopropionic acid, MPA) were insoluble in BTA (FIG. 7). We therefore developed stable blend CQD inks consisting of CTA-reprogrammed p-type inks and n-type CQD inks (FIG. 6C). Henceforth, we define p-type CQD inks as CTA-reprogrammed CQD inks.

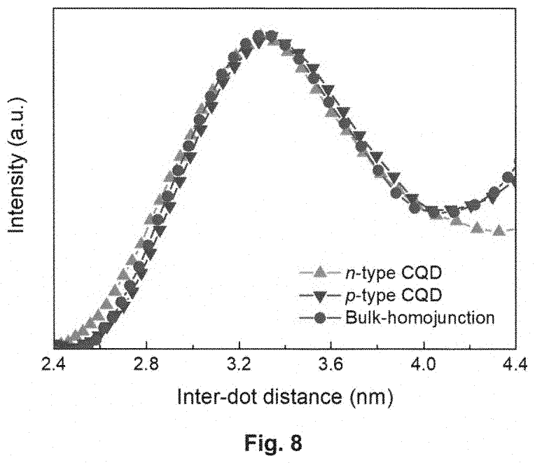

To investigate the impact of colloidal stability of inks on the final film formation and morphology, grazing-incidence small-angle X-ray scattering (GISAXS) measurements were carried out. For the CQD bulk homojunction film made from CSM inks, intensity accumulation indicates a hexagonal pattern and in-plane ordering of CQDs (FIG. 6D)⁹. Notably, conventional inks lose packing uniformity and do not show a clear hexagonal pattern in the final CQD solid (FIG. 6E). Azimuthal integration of the diffraction pattern shows an average inter-dot distance of 3.32 nm for CQD bulk homojunction film with CSM inks (FIG. 6F). Comparatively, inter-dot distances of 3.30 nm for the n-type CQD film and 3.35 nm for the p-type CQD film were found (FIG. 8). This agrees with the picture that a substantially homogeneous CQD bulk homojunction film is formed.

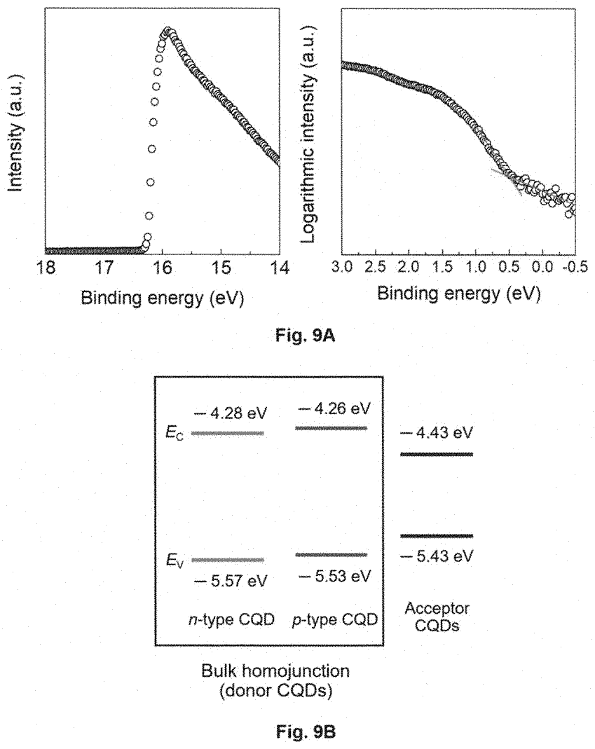

The carrier diffusion length of CQD bulk homojunction films made from CSM inks were investigated using a one-dimensional donor-acceptor scheme¹⁰ in which incident light excites the top donor CQD layer (E_{g}=1.3 eV, diffusive layer) and the photoexcited carriers transport to the bottom acceptor CQD layer (E_{g}=1.0 eV, emitter) where they can recombine radiatively (see Methods for sample preparation). Given the different solubility properties between the donor CQDs and the acceptor CQDs, the inventors opted to avoid three-dimensional donor-acceptor scheme¹¹, because it would be difficult to gauge if the acceptor CQDs would homogeneously mix with the donor CQDs. UPS measurements show that the energy level of the acceptor CQD layer forms a type-1 heterojunction with both n-type CQDs and p-type CQDs, making it suitable to be used as quencher in the 1-D diffusion length studies (FIG. 9).

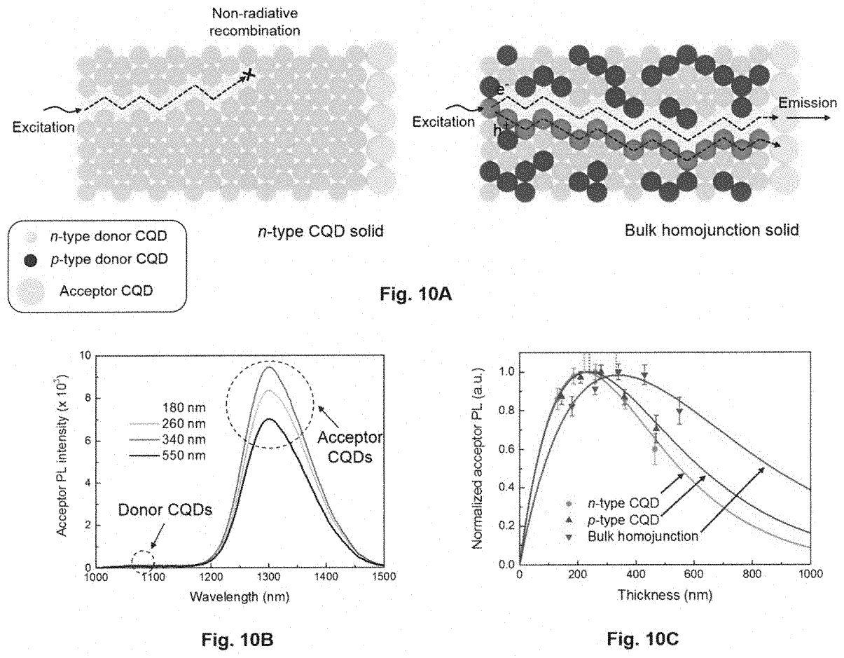

This recombination was monitored as a function of thickness of the donor layer (FIG. 10A). As the thickness of the donor layer is increased, the photoluminescence (PL) intensity of the acceptor layer starts to decrease after certain thickness are reached (FIG. 10B), when fewer charge carriers reach the acceptor layer due to non-radiative recombination in the diffusive layer. Normalized acceptor PL intensity is plotted as a function of donor layer thickness (FIG. 10C). To evaluate the carrier diffusion length, we fit the data using a 1-D diffusion length model¹⁰. It indicates that the CQD bulk homojunction films show longer carrier diffusion lengths (340 nm) by a factor of 1.5× compared to that of the previous best CQD control films (221 nm), which consist of only n-type halogenated CQDs.

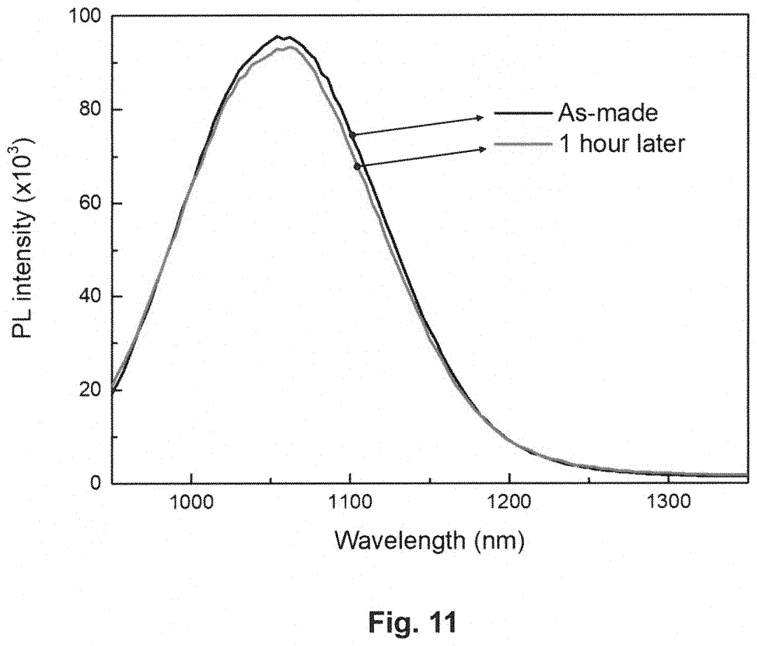

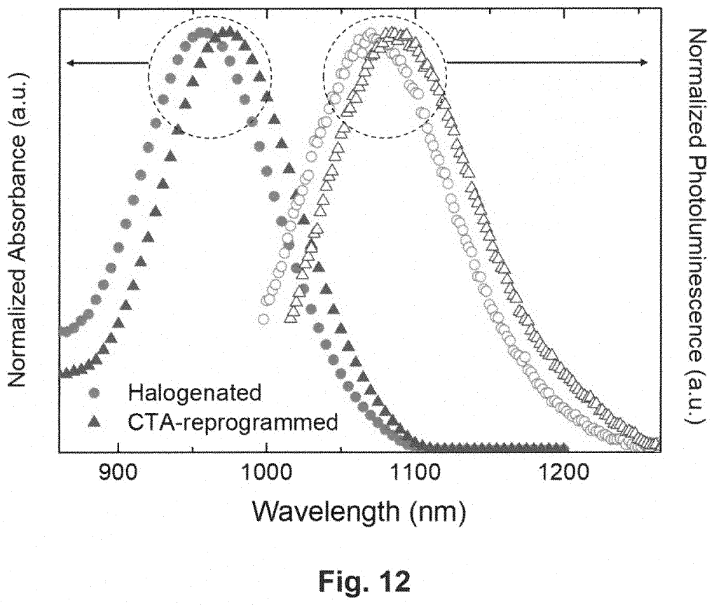

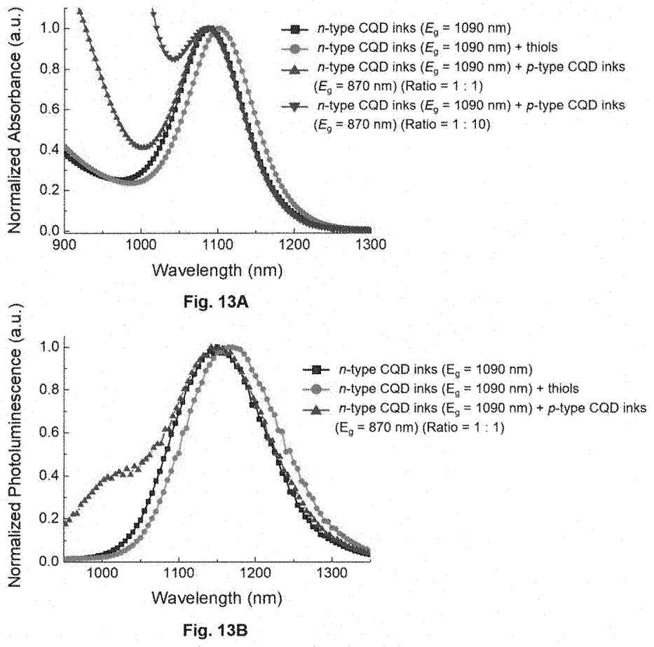

The orthogonality in the surface chemistry of p-type and n-type CQD inks in blend solution (their ability to retain their surface ligands when mixed in solution and in solid state), as well as their stability, were also studied to verify the retention of their original band offset. The blend inks show stable PL intensity for an hour, indicating no appreciable evolution in chemistry in the solution phase (FIG. 11). We then prepared blend inks consisting of wide E_{g} p-type inks (E_{g}=870 nm) and narrow E_{g} n-type inks (E_{g}=1090 nm). Because thiol passivation induces a red shift in the first excitonic peak (FIG. 12), we used it as a proxy to monitor thiol migration from p-type to n-type species. The addition of CTA in n-type inks produces a significant red shift in the first excitonic peak. In contrast, the blend inks do not show a peak shift in the n-type CQD population (FIG. 13). Taken together, the stable PL intensity of the blend inks, combined with the invariance in the peak position of the n-type CQD inks, indicate the retention of chemical orthogonality in, and the colloidal stability of, the blend inks.

The dynamics of charge carrier transfer between the constituent classes of CQDs were studied. The PL intensity of blend films consisting of n-type CQDs and p-type CQDs having the same size and bandgap (E_{g}=950 nm) exhibits strong emission quenching compared to that of purely n-type CQD and p-type CQD films, a signature of charge carrier transfer in the blend films (FIG. 14). We then carried out ultrafast transient absorption (TA) spectroscopy for more information. First we prepared blend CQD films consisting of a wide E_{g} p-type CQDs (E_{g}=980 nm) and a narrow E_{g} n-type CQD (E_{g}=1090 nm) to identify the charge transfer dynamics between the two populations.

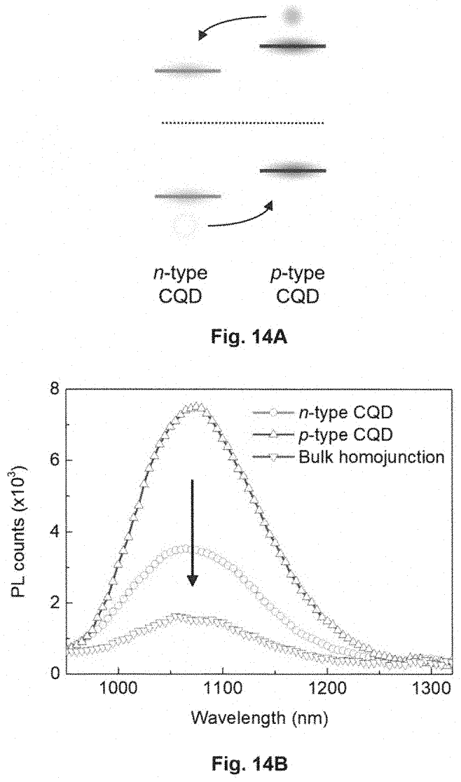

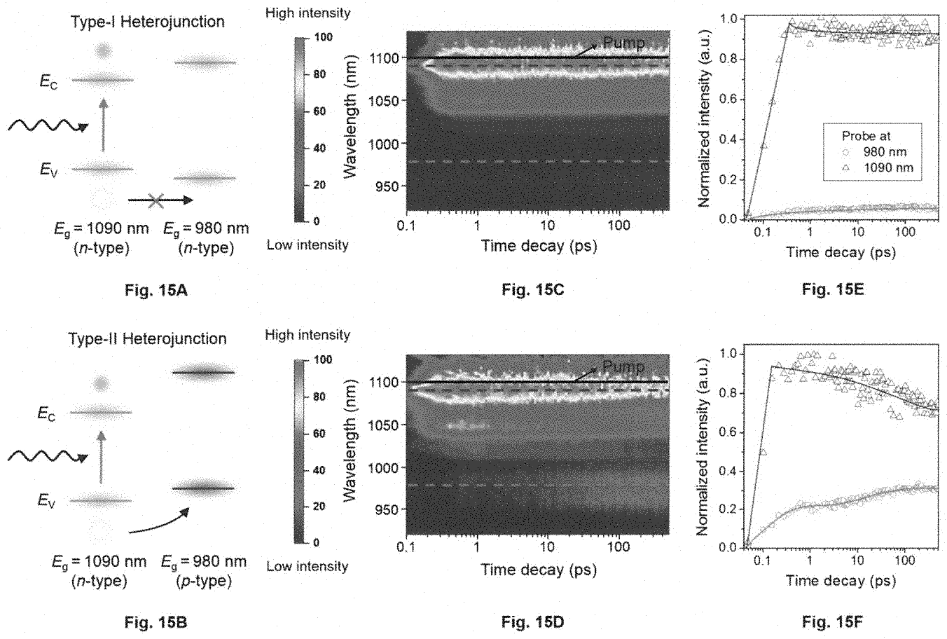

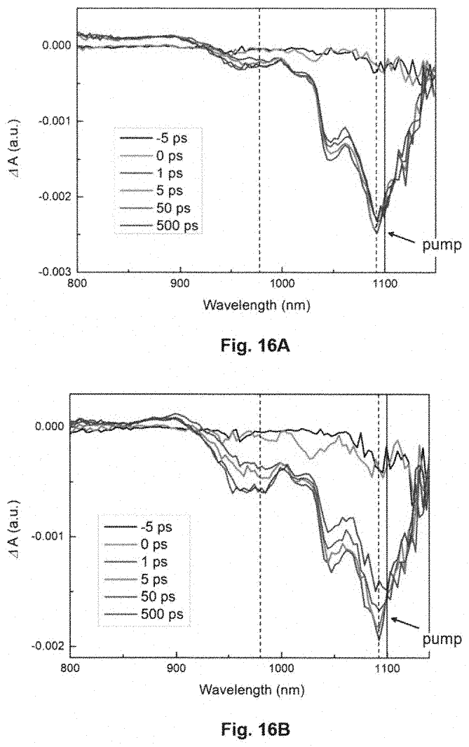

The inventors selectively populated the narrow bandgap CQDs using a photoexcitation wavelength of 1100 nm. In this configuration, charge carrier transfer from narrow to wide E_{g} CQDs will be indicated by the appearance of an increasing exciton bleach signal in the TA spectra at the corresponding wavelength. Kinetic traces of signal amplitude at wavelengths corresponding to the p-type and n-type CQD bandedge exciton bleach confirm charge carrier transfer from narrow E_{g} to wide E_{g} (FIG. 15D, 15f, and FIG. 16), evidenced in the rapid increase in the signal at 980 nm and the simultaneous decrease of the signal at 1090 nm. This evidences a functioning type-II heterojunction between p-type and n-type CQDs (FIG. 15B), indicating that holes are undergoing charge transfer from larger to smaller CODs¹¹. When using instead a mixture of different sized n-type CQDs (i.e. same surface functionalization but different E_{g}), this produces a type- I heterojunction (FIG. 15A), and there is no appreciable electron or hole transfer between the two spectrally distinct CQDs, evidenced by the lack of signal amplitude exchanged between the two bandedge exciton bleach peaks (FIG. 15C and 15E).

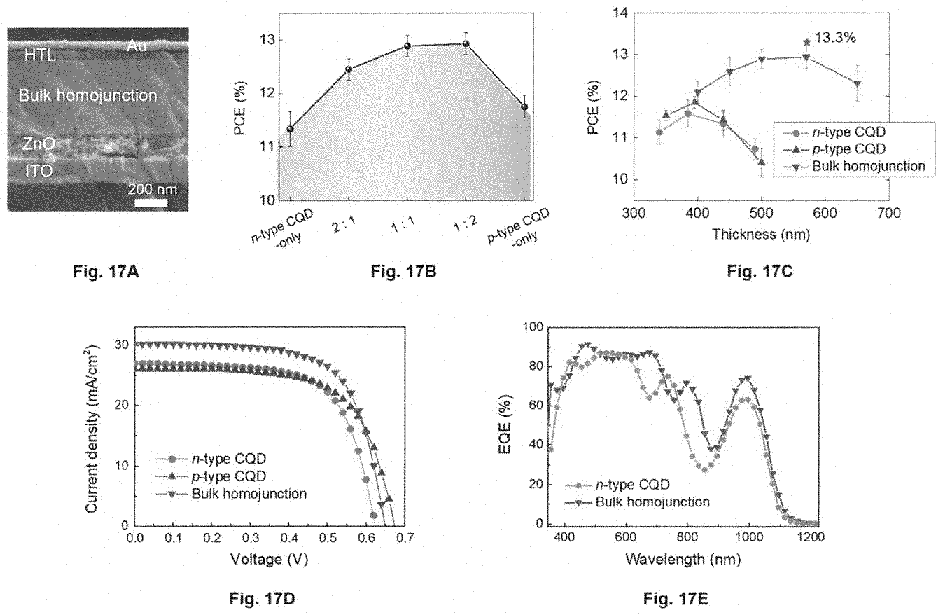

Given these promising properties of CQD bulk homojunction films, we pursued the realization of enhanced-performance in CQD solar cells. We employed CQD bulk homojunction films as the active layer in a conventional CQD solar cell structure: ITO/ZnO as electron-accepting layer/CQD film as active layer/thin CQD film treated with 1,2-ethanethiol (EDT) as hole-transport layer/Au (FIG. 17A). We note that p-type CQD inks cannot be employed as the HTL in CQD devices due to their similar solubility properties to those of the n-type CQD inks. We first sought to optimize the p-type to n-type CQD ratio and obtained our best PCE using a 2:1 mass ratio (FIG. 17B).

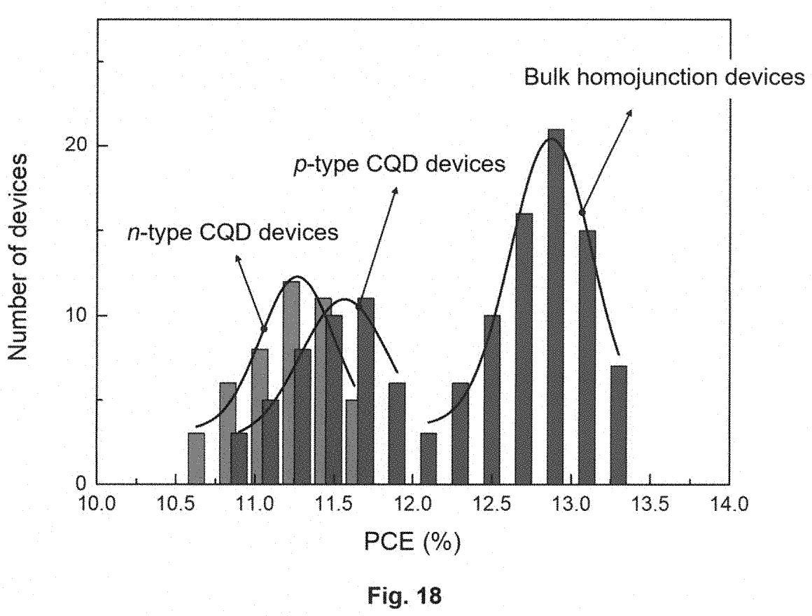

The inventors then explored the thickness-dependent PCE. Notably, the bulk homojunction devices exhibit a substantially greater optimized thickness (˜580 nm) compared to the devices based on n-type CQDs (˜390 nm) and p-type CQDs (˜400 nm) (FIG. 17C), which is in good agreement with our observations of longer carrier diffusion lengths in the bulk homojunction films. This was accompanied by an enhanced J_{SC} without compromise to V_{OC} and FF; and as a result it led to superior PCE. Using this architecture, we achieved an AM1.5 PCE of 13.3% through the combination of V_{OC} of 0.65 V, J_{SC} of 30.2 mA/cm², and FF of 68% (FIG. 17D). The AM1.5 PCE from an accredited laboratory (Newport) shows a value of 12.47±0.33%, the highest certified PCE reported for CQD solar cells. The devices with p-type CQDs exhibit higher V_{OC} compared to the devices with n-type CQDs. The downshifted Fermi level of p-type CQDs increases the built-in potential of devices, accounting for the higher V_{OC}. Statistical data of the bulk homojunction devices show the reproducibility of these efficiencies (FIG. 18).

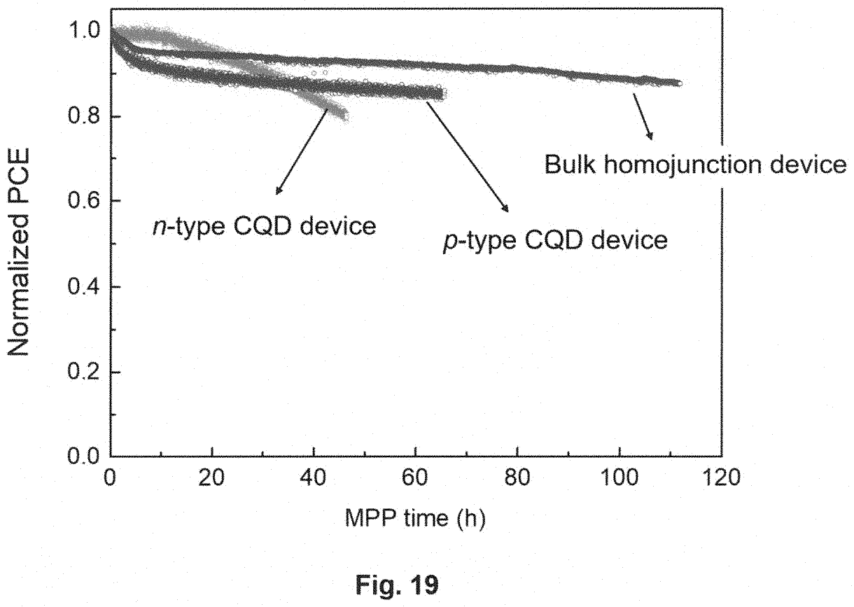

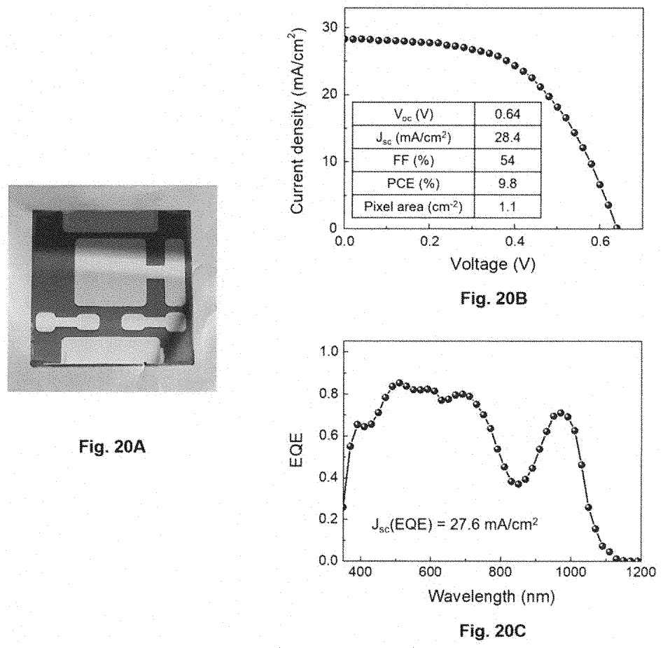

External quantum efficiency (EQE) measurements confirm the high J_{SC} of the bulk homojunction device (30.0 mA/cm²) compared to the control device (26.8 mA/cm²) (FIG. 17e). We further tested the stability of the CQD bulk homojunction devices. They retained 87% of their initial PCE following 110 h of device operation at their maximum power point under AM1.5G illumination in an N₂ atmosphere (FIG. 19). We made larger-area (1.1 cm²) devices using CQD bulk homojunctions (FIG. 20) and obtained similar V_{OC} and J_{SC} values. A somewhat lower PCE in large-area devices comes from a lower FF related to the series resistance of the transparent conductive oxide³.

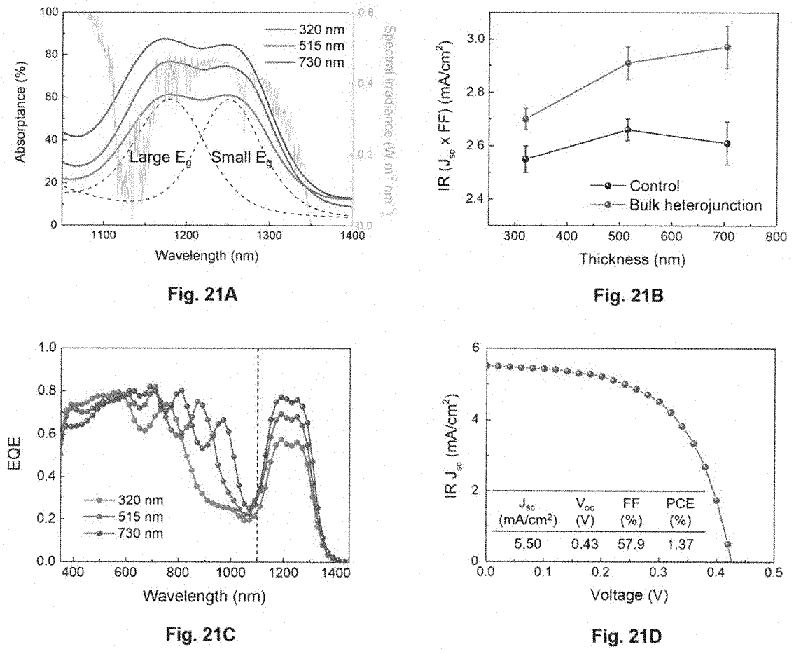

CQD solar cells that can harvest the IR light were fabricated by mixing n-type CQDs (E_{g}=1250 nm) and p-type CQDs (E_{g}=1180 nm). The absorption spectra of the CQD bulk heterojunction devices match with the IR light in the AM1.5 solar spectrum that enable to harvest most of the light in the range of 1100-1400 nm (FIG. 21A). As the thickness of active layer is increased from 320 nm to 730 nm, the CQD bulk heterojunction devices exhibit consistently higher value of J_{SC}×FF. In contrast, the J_{SC}×FF for the control devices—mixed with n-type CQDs (E_{g}=1250 nm) and n-type CQDs (E_{g}=1180 nm)—decreases when the active layer is thicker than 515 nm (FIG. 21B). The three representative thickness (320 nm, 515 nm, 730 nm) of the active layer were selected to maximize light absorption, considering light reflected on the gold electrode. The EQE of the CQD bulk heterojunction devices consistently increases with thicker active layer and reaches ˜80% along the IR light at the thickness of 730 nm, corresponding to 5.50 mA/cm² with 1100 nm long-pass filter (FIG. 21C). This champion device achieves an Voc of 0.43 V, and a FF of 57.9% after 1100 nm long-pass filter, resulting in an IR PCE of 7.0% and capability to add the extra PCE of 1.37% to c-Si solar cells (FIG. 21D).

### Discussion

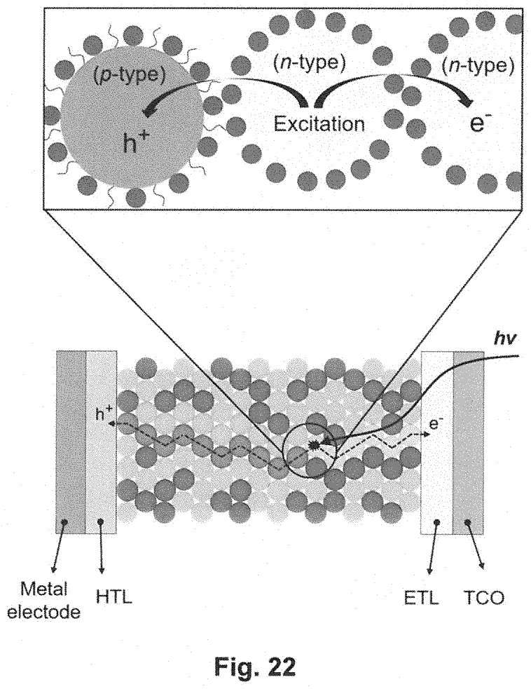

This work introduces a way to realize the homogeneous bulk homojunction structure in CQD solids. It is achieved via development of a CSM ligand-exchange strategy that enables the synthesis of p-type and n-type CQD inks that combine excellent surface passivation with miscibility for stable mixed-dot colloids. The CQD bulk homojunction films show an increase in carrier diffusion length compared to the state-of-art planar CQD films owing to improved separation and transport of photoexcited carriers through distinct physical paths. This is supported by observations of ultrafast charge transfer between n and p-type domains as probed using transient absorption spectroscopy. The resulting solar cells exhibit the highest power conversion efficiency (PCE) reported in CQD photovoltaic devices (13.3%): which is enabled by efficient collection of photoexcited carriers through bulk heterojunction structure (FIG. 22). In addition, different combination of CQDs results in the fabrication of bulk heterojunction CQD solids, which we show here efficient IR CQD solar cells, exhibiting IR PCE of 7.0%.

Thus, embodiments of the nano-composite are provided herein as follows.

In a first embodiment, there is provided a method of preparing a doped and solvent stabilized inorganic nanocrystal, the inorganic nanocrystal having a facetted surface with long chain ligands attached thereto, the method comprising the steps of:
exposing the nanocrystal to a solvent containing doping agents and stabilisation agents for inducing a ligand exchange reaction to remove substantially all the long chain ligands to be replaced by the stabilisation agents and doping agents bound to the facetted surface, said doping agents being selected to render the nanocrystal either an n-type or p-type doped nanocrystal, and the stabilisation agents being selected to provide long-term stability of the nanocrytal in the solvent.

In an embodiment, the doping and stabilization agent are the same compound, being a combined doping and stabilization agent, said compound having a first moeity which interacts with the surface of the facetted surface to provide doping of the inorganic nanocrystal, said compound having a second moeity which interacts with the selected solvent to stabilize the inorganic nanocrystal in said selected solvent.

In an embodiment, the combined doping and stabilization agent is selected from the group consisting of cysteamine, mercaptoethanol, hydroxythiophenol, aminothiophenol, mercaptopropionic acid and thioglycerol.

In an embodiment, prior to exposing the nano-composite inorganic nanocrystal to the solvent containing the doping and stabilisation agents, exposing the inorganic nanocrystal to a solvent containing passivation agents, thereby inducing a ligand exchange reaction to remove substantially all the long chain ligands to be replaced by the passivating agents to form passivated nanocrystals, followed by exposing the passivated nanocrystals to a solvent containing said doping and stabilisation agents to replace some of the passivating agents and bind to at least some sites not occupied by the passivating agents.

In embodiments the passivating agents are any one or combination of halides and metal chalcogenide complexes.

In embodiments the passivating agents are any one or combination of sulfide complexes.

In embodiments the sulfide complexes are selected from the group consisting of sodium sulfide (Na₂S), ammonium sulfide ((NH₄)₂S), potassium sulfide (K₂S), tin sulfide and copper suldie.

In embodiments a ratio of the doping agents to the passivation agents is about 2:1.

In embodiments the doping and stabilization agents are different compounds, wherein said stabilization agent has a first moeity which bonds to the facetted surface, and wherein said stabilization agent has a second moeity which interacts with the selected solvent to stabilize the inorganic nanocrystal in said selected solvent.

In embodiments the doping agent is selected from the group consisting of ethanethiol, propanethiol, formic acid, acetic acid, propionic acid and thiophenol.

In embodiments the stabilization agent is selected from the group consisting of ethylenediamine, propylenediamin and butylamine.

In embodiments the two or more types of inorganic nanocrystals are selected from the group consisting of Bi₂S₃, FeS₂ (pyrite), FeS, iron oxide, ZnO, TiO₂, copper sulfide, PbS, PbSe, PbTe, CdSe, CdS, Si, Ge, copper zinc tin sulfide (CZTS), HgTe, CdHgTe and copper indium gallium diselenide (CIGS); InAs, InₓGa₁₋ₓAs (X: 0-1) AgS, AgSe; and core-shell structures based on these CQDs as the core; ternary or multinary compounds based on the above.

These nano-composite inorganic nanocrystals are characterized by a long-term stability is at least 30 minutes.

In embodiments a second

In a second embodiment there is provided a method of preparing a solvent stabilized nano-composite material, comprising:
providing two or more types of inorganic nanocrystals having facetted surfaces, each type having a composition different from the other types, and/or each type having a different size from the other types;
separately exposing each type to a preselected a solvent containing doping agents and stabilisation agents for inducing a ligand exchange reaction to remove substantially all long chain ligands initially present on surfaces of the each type of inorganic nanocrystals to be replaced by the stabilisation agents and doping agents bound to the facetted surface, said doping agents being selected to render the mixture of each type either an n-type or p-type doped nanocrystal, and the stabilisation agents being selected to provide long-term stability of each type in the solvent; and
mixing said doped and stabilized types in said solvent.

In this second embodiment each type of inorganic nanocrystal, the doping and stabilization agents are the same compound, being a combined doping and stabilization agent, said compound having a first moeity which interacts with the surface of the facetted surface to provide doping of the inorganic nanocrystal, said compound having a second moeity which interacts with the selected solvent to stabilize the inorganic nanocrystal in said selected solvent.

In this second embodiment the combined doping and stabilization agent is selected from the group consisting of cysteamine, mercaptoethanol, hydroxythiophenol, aminothiophenol, mercaptopropionic acid and thioglycerol.

In this second embodiment, prior to exposing the inorganic nanocrystal to the solvent containing the doping and stabilisation agents, exposing the inorganic nanocrystal to a solvent containing passivation agents, thereby inducing a ligand exchange reaction to remove substantially all the long chain ligands to be replaced by the passivating agents to form passivated nanocrystals, followed by exposing the passivated nanocrystals to a solvent containing said doping and stabilisation agents to replace some of the passivating agents and bind to at least some sites not occupied by the passivating agents.

In this second embodiment, the passivating agents are any one or combination of halides and metal chalcogenide complexes.

In this second embodiment, the passivating agents are any one or combination of sulfide complexes.

In this second embodiment, the sulfide complexes are selected from the group consisting of sodium sulfide (Na₂S), ammonium sulfide ((NH₄)₂S), potassium sulfide (K₂S), tin sulfide and copper suldie.

In this second embodiment, a ratio of the doping agents to the passivation agents is about 2:1.

In this second embodiment, for each type of nanocrystal the doping and stabilization agents are different compounds, wherein said stabilization agent has a first moeity which bonds to the facetted surface, and wherein said stabilization agent has a second moeity which interacts with the selected solvent to stabilize the inorganic nanocrystal in said selected solvent.

In this second embodiment, the doping agent is selected from the group consisting of ethanethiol, propanethiol, formic acid, acetic acid, propionic acid and thiophenol.

In this second embodiment, the stabilization agent is selected from the group consisting of ethylenediamine, propylenediamin and butylamine.

In this second embodiment, the two or more types of inorganic nanocrystals are selected from the group consisting of Bi₂S₃, FeS₂ (pyrite), FeS, iron oxide, ZnO, TiO₂, copper sulfide, PbS, PbSe, PbTe, CdSe, CdS, Si, Ge, copper zinc tin sulfide (CZTS), HgTe, CdHgTe and copper indium gallium diselenide (CIGS); InAs, InₓGa₁₋ₓAs (X: 0-1) AgS, AgSe; and core-shell structures based on these CQDs as the core; ternary or multinary compounds based on the above.

In this second embodiment, the long-term stability of the nano-composite nanocrystals is at least 30 minutes.

Therefore what is claimed is:

1. An inorganic nanocrystal having a facetted surface, comprising:
doping agents bound to the facetted surface of the nanocrystal to render the nanocrystal either an n-type or p-type doped nanocrystal; and
stabilisation agents bound to the surface of the facetted surface of the nanocrystal to provide long-term stability of the nanocrytal in a selected solvent.

2. The inorganic nanocrystal of claim 1, further comprising passivating agents bound to the facetted surface of the inorganic nanocrystal.

3. The inorganic nanocrystal of claim 2, wherein the passivating agents are any one or combination of halides and metal chalcogenide complexes.

4. The inorganic nanocrystal of claim 2, wherein the passivating agents are any one or combination of sulfide complexes.

5. The inorganic nanocrystal of claim 4, wherein the sulfide complexes are selected from the group consisting of sodium sulfide (Na₂S), ammonium sulfide ((NH₄)₂S), potassium sulfide (K₂S), tin sulfide and copper sulfide.

6. The inorganic nanocrystal according to claim 1, wherein the doping and stabilization agent are the same compound, being a combined doping and stabilization agent, said compound having a first moeity which interacts with the surface of the facetted surface to provide doping of the inorganic nanocrystal, said compound having a second moeity which interacts with the selected solvent to stabilize the inorganic nanocrystal in said selected solvent.

7. The inorganic nanocrystal according to claim 6, wherein the combined doping and stabilization agent is selected from the group consisting of cysteamine, mercaptoethanol, hydroxythiophenol, aminothiophenol, mercaptopropionic acid and thioglycerol.

8. The inorganic nanocrystal according to claim 6, wherein a ratio of the doping agents to the passivation agents is about 2:1.

9. The inorganic nanocrystal according to claim 1, wherein the doping and stabilization agents are different compounds, wherein said stabilization agent has a first moeity which bonds to the facetted surface, and wherein said stabilization agent has a second moeity which interacts with the selected solvent to stabilize the inorganic nanocrystal in said selected solvent.

10. The inorganic nanocrystal according to claim 9, wherein the doping agent is selected from the group consisting of ethanethiol, propanethiol, formic acid, acetic acid, propionic acid and thiophenol.

11. The inorganic nanocrystal according to claim 9, wherein the stabilization agent is selected from the group consisting of ethylenediamine, propylenediamin and butylamine.

12. The inorganic nanocrystal according to claim 1, wherein the multifaceted nanocrystal is selected from the group consisting of Bi₂S_{3,} FeS₂ (pyrite), FeS, iron oxide, ZnO, TiO₂, copper sulfide, PbS, PbSe, PbTe, CdSe, CdS, Si, Ge, copper zinc tin sulfide (CZTS), HgTe, CdHgTe and copper indium gallium diselenide (CIGS); InAs, InₓGa₁₋ₓAs (X: 0-1) AgS, AgSe; and core-shell structures based on these CQDs as the core; ternary or multinary compounds based on the above.

13. A nano-composite material, comprising:
a mixture of two or more types of inorganic nanocrystals having facetted surfaces, each type having a composition different from the other types, and/or each type having a different size from the other types;
each type of inorganic nanocrystal having doping agents bound to the facetted surfaces of the nanocrystals to render the nanocrystals either an n-type or p-type doped nanocrystal; and
each type of inorganic nanocrystal having stabilisation agents bound to the facetted surfaces to provide long-term stability of the nanocrytal in a selected solvent, the stabilization agents bound to the facetted surfaces of one type of inorganic nanocrystal being selected to not interact with the facetted surfaces of the other types of inorganic nanocrystals.

14. The nano-composite material according to claim 13, further comprising passivating agents bound to the facetted surface of the inorganic nanocrystal.

15. The nano-composite material according to claim 13, wherein the passivating agents are any one or combination of halides and metal chalcogenide complexes.

16. The nano-composite material according to claim 13, wherein the passivating agents are any one or combination of sulfide complexes.

17. The nano-composite material according to claim 16, wherein the sulfide complexes are selected from the group consisting of sodium sulfide (Na₂S), ammonium sulfide ((NH₄)₂S), potassium sulfide (K₂S), tin sulfide and copper suldie.

18. The nano-composite material according to claim 13, wherein the doping and stabilization agent are the same compound, being a combined doping and stabilization agent, said compound having a first moeity which interacts with the surface of the facetted surface to provide doping of the inorganic nanocrystal, said compound having a second moeity which interacts with the selected solvent to stabilize the inorganic nanocrystal in said selected solvent.

19. The nano-composite material according to claim 18, wherein the combined doping and stabilization agent is selected from the group consisting of cysteamine, mercaptoethanol, hydroxythiophenol, aminothiophenol, mercaptopropionic acid and thioglycerol.

20. The nano-composite according to claim 18, wherein a ratio of the doping agents to the passivation agents is about 2:1.

21. The nano-composite material according to claim 13, wherein the doping and stabilization agents are different compounds, wherein said stabilization agent has a first moeity which bonds to the facetted surface, and wherein said stabilization agent has a second moeity which interacts with the selected solvent to stabilize the inorganic nanocrystal in said selected solvent.

22. The nano-composite material according to claim 21, wherein the doping agent is selected from the group consisting of ethanethiol, propanethiol, formic acid, acetic acid, propionic acid and thiophenol.

23. The nano-composite material according to claim 21, wherein the stabilization agent is selected from the group consisting of ethylenediamine, propylenediamine and butylamine.

24. The nano-composite material according to claim 13, wherein the two or more types of inorganic nanocrystals are selected from the group consisting of Bi₂S₃, FeS₂ (pyrite), FeS, iron oxide, ZnO, TiO₂, copper sulfide, PbS, PbSe, PbTe, CdSe, CdS, Si, Ge, copper zinc tin sulfide (CZTS), HgTe, CdHgTe and copper indium gallium diselenide (CIGS); InAs, InₓGa₁₋ₓAs (X: 0-1) AgS, AgSe; and core-shell structures based on these CQDs as the core; ternary or multinary compounds based on the above.
